(19) United States
(12) Patent Application Publication
(10) Pub. No.: US 2015/0319893 A1
(43) Pub. Date: Nov. 5, 2015

(54) SEPARATION APPARATUS FOR THIN FILM STACKED BODY

(71) Applicant: SEMICONDUCTOR ENERGY LABORATORY CO., LTD., Atsugi-shi (JP)

(72) Inventors: Masakatsu OHNO, Utsunomiya (JP); Satoru IDOJIRI, Tochigi (JP); Koichi TAKESHIMA, Sano (JP); Kayo KUMAKURA, Tochigi (JP); Yoshiharu HIRAKATA, Ebina (JP); Kohei YOKOYAMA, Fujisawa (JP)

(21) Appl. No.: 14/696,525

(22) Filed: Apr. 27, 2015

(30) Foreign Application Priority Data
May 3, 2014 (JP) 2014-095580

(51) Int. Cl. H05K 13/04; B32B 38/10; B32B 43/00

(52) U.S. Cl. CPC H05K 13/0486; B32B 43/006; B32B 38/10

(57) ABSTRACT

A separation apparatus (1) for separating a thin-film flexible stacked body (3) from a component (16) where the thin-film flexible stacked body (3) including an element layer is formed over a rigid substrate (2) such as a glass substrate, a quartz substrate, a ceramic substrate, or a metal substrate is provided. The separation apparatus (1) mainly includes a fixing device (10) for fixing the substrate (2) of the component (16), suction jigs (11) for lifting the flexible stacked body (3) by suction to be separated, circular suction pads (13) that are brought into direct contact with the flexible stacked body (3) and attached to the flexible stacked body (3) by suction, and clamp jigs (9) for holding an edge of the flexible stacked body (3). A position sensor such as a laser measuring instrument for measuring or monitoring a separation state of the flexible stacked body may be used together.

### TECHNICAL FIELD

The present invention relates to a separation apparatus for a thin film stacked body to be used in an electronic device. More specifically, the present invention relates to a separation apparatus for a thin film stacked body, to separate a flexible thin film stacked body from a stacked body where an element layer including a light-emitting element, a power generation element, a power storage element, a display element, a memory element, a semiconductor element, or the like is formed.

### BACKGROUND ART

In recent years, devices in which a functional element such as a semiconductor element, a display element, or a light-emitting element is provided over a substrate having flexibility (hereinafter also referred to as a flexible substrate) have been researched and developed, and have been put into practical use. Typical examples of a flexible device include, as well as a lighting device and an image display device, a variety of semiconductor circuits including a semiconductor element such as a transistor. When components that constitute the device such as a lighting device or an image display device are formed directly on a flexible substrate, the upper-limit temperature of a manufacturing process needs to be set relatively low because a material for the flexible substrate has low heat resistance. For this reason, the quality of the components of the device might be reduced.

Furthermore, in the case where alignment is required in the manufacturing process, expansion and contraction of the flexible substrate due to heating in the manufacturing process might reduce the yield. Accordingly, to reasonably perform various heating steps, alignment steps, and the like in a manufacturing process of a device, a module, or the like using a flexible substrate; it is preferable that the steps be performed on a rigid substrate such as a glass substrate, and that a stacked body formed on the rigid substrate be separated from the rigid substrate and then transferred to the flexible substrate in the final stage of the manufacturing process. In view of this, a variety of techniques for separating a stacked body have been proposed. For example, a technique in which a separation layer is irradiated with light and a cut is formed by a blade, separation is induced by blow of a gas from the cut, and a rigid substrate is drawn up by suction portions such that the separation extends to the whole area of the separation layer has been proposed (see Patent Document 1, for example).

### REFERENCE

### Patent Document

[Patent Document 1] Japanese Published Patent Application No. 2010-50313

### DISCLOSURE OF INVENTION

As described above, a variety of separation apparatuses have been proposed and the techniques have already been used widely. However, any of the current separation apparatuses is actually not perfect, and there is still room for improvement. Specifically, when separation proceeds from a separation starting point along a plurality of suction portions, part of a stacked body deforms because of its bending or warp; accordingly, it is difficult for conventional suction portions to follow the deformation and keep attached to the stacked body, resulting in detachment of the suction potions or the like. Thus, separation of the stacked body cannot be performed normally. That is, problems such as lack of stability of a suction state prevented the separation from being always performed uniformly and with high quality. The reason for this is that the state of sucking a flexible substrate has not necessarily been perfect.

The present invention was made to solve the above-described conventional problems, and achieved the following object. An object of one embodiment of the present invention is to provide a separation apparatus for a thin film stacked body, which enables a stable suction state, follows the shape of a stacked body without detachment of suction portions, and produces no defect such as bending or wrinkles

In order to achieve the above object, one embodiment of the present invention can be obtained by the following means. That is, a separation apparatus for a thin film stacked body of Invention 1 is an apparatus for separating a thin-film flexible stacked body from a component where the thin-film flexible stacked body including an element layer is formed over a substrate.

The separation apparatus includes a fixing jig for fixing the substrate, a plurality of suction jigs for sucking the flexible stacked body, and a clamp jig for holding an edge of the flexible stacked body separated using the suction jigs. The suction jigs each include a plurality of suction pads that are brought into direct contact with the flexible stacked body and attached to the flexible stacked body by suction.

Invention 2 is the separation apparatus for a thin film stacked body according to Invention 1, in which the substrate and the component are each a square or a rectangle. Invention 3 is the separation apparatus for a thin film stacked body according to Invention 1 or 2, further including a needle provided adjacent to the component in order to stick a separation starting point for separating the flexible stacked body from the component.

Invention 4 is the separation apparatus for a thin film stacked body according to any one of Inventions 1 to 3, further including a nozzle provided adjacent to the component in order to supply a liquid to a separation area of the flexible stacked body. Invention 5 is the separation apparatus for a thin film stacked body according to any one of Inventions 1 to 4, in which the suction jigs are placed in an initial motion position where the flexible stacked body starts to be separated from the component and a separation complete position where the separation completes.

Invention 6 is the separation apparatus for a thin film stacked body according to any one of Inventions 1 to 5, in which an end portion of the suction pad, which is capable of being attached to the flexible stacked body by suction, is formed into a circular shape. Invention 7 is the separation apparatus for a thin film stacked body according to any one of Inventions 1 to 6, in which a measuring instrument for sensing a position of the flexible stacked body that is separated from the substrate using the suction jigs is provided near the flexible stacked body.

Since the separation apparatus for a thin film stacked body of one embodiment of the present invention has the plurality of suction pads arranged on each of the suction jigs, when the suction pads are attached to the surface of a flexible stacked body, suction that follows the surface state of the flexible stacked body is achieved. In addition, as the number of suction points increases, reliability of the suction improves. Furthermore, using the clamp jig together makes it possible for the separation to be performed with a stable suction state, good follow-up of the shape of a flexible stacked body without detachment of suction portions, and no defect such as bending or wrinkles Furthermore, a stable separation operation becomes possible because the progress of the separation is measured and the separation state is constantly monitored.

### BRIEF DESCRIPTION OF DRAWINGS

In the accompanying drawings:

FIG. 1 is a development view illustrating a structure of a separation apparatus for a thin film stacked body of one embodiment of the present invention;

FIG. 2 is a diagram showing a cut of a separation area of a separation object;

FIG. 3 is a development view illustrating a standby state of a separation apparatus for a thin film stacked body;

FIG. 4 is a development view illustrating a suction state of a separation apparatus for a thin film stacked body;

FIG. 5 is a development view illustrating a state where a flexible stacked body is lifted by a separation apparatus for a flexible stacked body using suction pads;

FIG. 6 is a development view illustrating a state where a flexible stacked body is inserted into and held by clamp jigs in a separation apparatus for a flexible stacked body;

FIG. 7 is a cross-sectional view showing a separation starting point of a separation object with a cut;

FIG. 8 is a diagram illustrating a structure of suction pads;

FIG. 9 is a cross-sectional view showing a structure of a clamp jig;

FIGS. 10A and 10B are diagrams illustrating how a flexible stacked body is separated with suction jigs and clamp jigs;

FIG. 11 is a diagram illustrating measurement using a laser measuring instrument; and

FIG. 12 is a flow chart for monitoring a separation state with laser measurement.

### BEST MODE FOR CARRYING OUT THE INVENTION

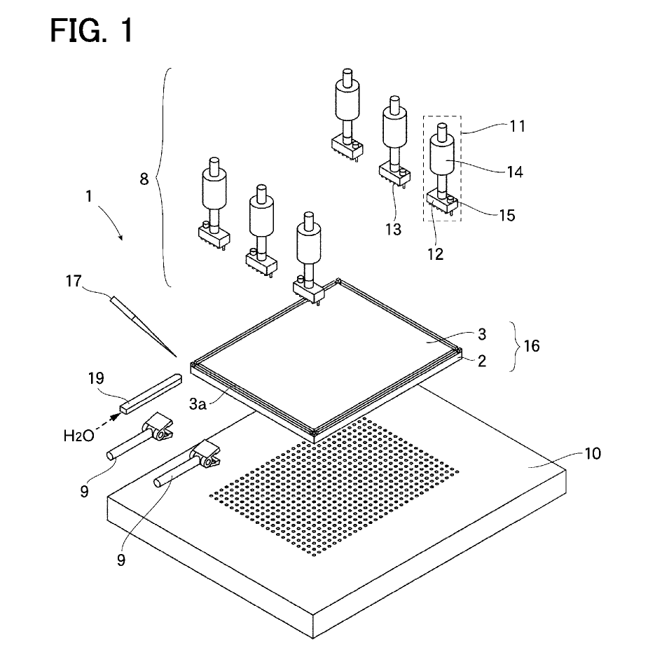

Embodiments of the present invention will be explained below with reference to the accompanying drawings. Note that detailed explanations of an apparatus or unit related to a flexible stacked body handled by the apparatus of the present invention will not be given. FIG. 1 is a perspective view showing a structure of a separation apparatus 1 of one embodiment of the present invention. The separation apparatus 1 is to separate a flexible stacked body 3 formed over a rigid substrate 2.

For the flexible stacked body 3 of this kind, a variety of structures has been proposed. In this example, the flexible stacked body 3 is made up of an element 4, an adhesive 5, and a flexible substrate 6 (see FIG. 7). As shown in FIG. 3 and the like, a separation object 16 is a stacked body in which the flexible stacked body 3 is firmly fixed to a substrate 2 with a separation layer 7 provided therebetween. It is needless to say that other stacked bodies having different structures than the flexible stacked body 3 of this embodiment may also be used as the stacked body. The rigid substrate 2 can be, for example, a glass substrate, a quartz substrate, a ceramic substrate, a metal substrate, a semiconductor substrate, or the like.

The separation apparatus 1 for separating the flexible stacked body 3 that is a thin film stacked body includes a suction mechanism 8 for sucking the flexible stacked body 3 and clamp jigs 9 for holding one edge of the flexible stacked body 3. The rigid substrate 2 is fixed to a fixing stage 10. Although the detail of how the rigid substrate 2 (or the separation object 16) is fixed to the fixing stage 10 is not shown, a fixing means such as vacuum suction or electrostatic attraction may be employed. The suction mechanism 8 includes a plurality of suction jigs 11. The suction jigs 11 are arranged above or near the flexible stacked body 3, can be moved up and down, left and right, and back and forth (i.e., in orthogonal triaxial directions) by a driving system that is not shown, and the positions thereof can also be controlled. In this example, six suction jigs 11 (two rows of three suction jigs 11) are provided.

The suction jigs 11 each include a block 12 under which six suction pads 13 are provided, in this example. The suction pads 13 are supported by a support 14 provided thereover with the block 12 therebetween. The suction pads 13 can be moved, along with the block 12, up and down relatively to the fixing stage 10 or the separation object 16. Furthermore, the block 12 is provided with an inlet 15 that is connected with each of the suction pads 13, whereby a vacuum pump P (see FIG. 8) is connected with each of the suction pads 13 via a piping. When the vacuum pump P operates, each of the suction pads 13 performs a sucking operation via the inlet 15.

Specifically, when each of the suction pads 13 moves downward to be in contact with the flexible stacked body 3 and the vacuum pump P operates or a valve operates to connect each of the suction pads 13 with the vacuum pump P, each of the suction pads 13 sucks the flexible stacked body 3 by a sucking operation. Then, only the necessary flexible stacked body 3 is separated from the separation object 16 fixed to the fixing stage 10. In this example, for separating the flexible stacked body 3 from the rigid substrate 2, a needle 17 to be stuck into a certain region to promote the separation is provided. The needle 17 is inserted between the flexible stacked body 3 and the rigid substrate 2 (e.g., into the separation layer 7 provided therebetween) to stick a starting position of a portion to be separated or the periphery of the separation area. The position where the needle 17 is stuck into is accurately controlled and set by a driving part not shown.

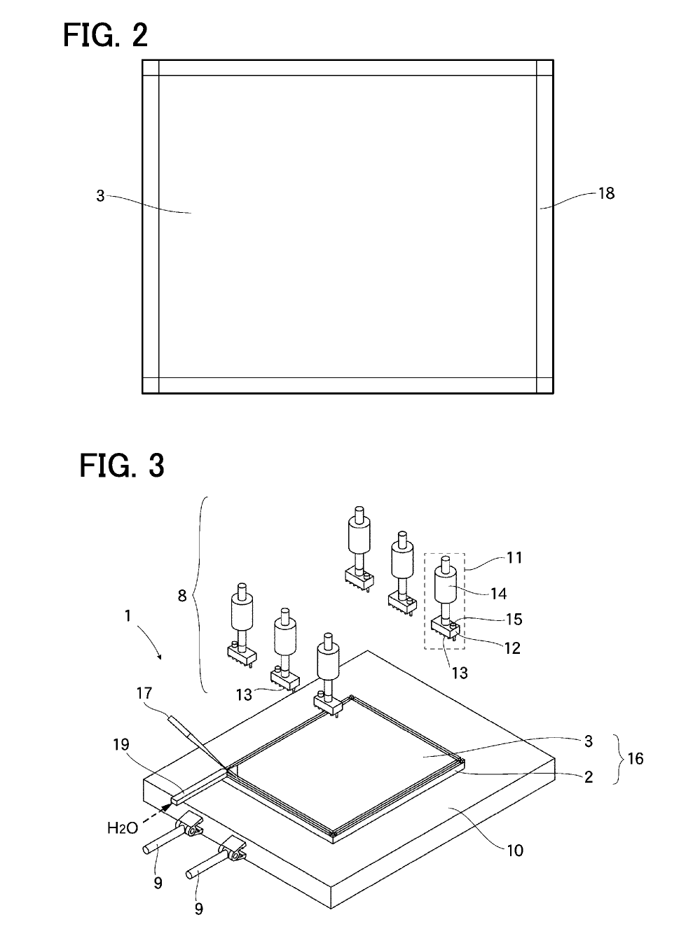

Before the separation process, for example, the separation object 16 is provided with a cut 18 as shown in FIG. 2, formed along the outer periphery of a rectangular portion of the flexible substrate 3 to be separated, with a preset depth, by another process. In FIG. 2, the cut 18 is made with a cutter-knife-like tool; however, this process is omitted in the case where the cut is not necessary. When the flexible stacked body 3 is separated after the cut is made, the peripheral part of the flexible stacked body 3 remains as a residue 22 (see FIG. 5).

The clamp jigs 9 for stably supporting the separation operation are provided adjacent to the separation object 16. The clamp jigs 9 hold an edge 3a of the separated flexible stacked body 3 and supply a certain tension to the flexible stacked body 3. In addition, a nozzle 19 (a water supplying nozzle, in this example) for supplying a liquid (e.g., water, preferably pure water, or an organic solvent) is provided adjacent to the separation object 16, and sprays the liquid into a separation interface at the time of separation. The presence of the liquid in the portion where the separation proceeds can decrease the power required for the separation. Moreover, in the case where the flexible stacked body 3 is an electronic device or the like, electrostatic discharge damage thereto can be prevented.

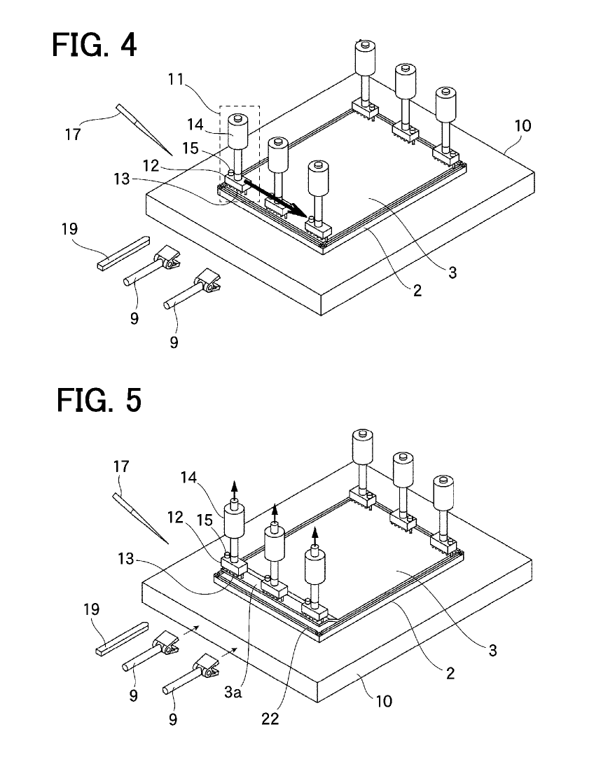

Next, each device included in the apparatus and the separation operation will be described. FIG. 3 illustrates the arrangement of the above-described structures, and shows an initial state where the separation object 16 is fixed to the fixing stage 10 and each device is on standby. FIG. 4 shows a sucking state. The separation object 16 is vacuum-sucked to the fixing stage 10 with the rigid substrate 2 down. The fixing may also be achieved by electrostatic attraction. The flexible stacked body 3 faces upward, and the suction mechanism 8 with six suction jigs 11 is provided thereover.

In FIG. 3, FIG. 4, and the like, the supports 14 that move the suction jigs 11 up and down individually are schematically shown. As described above, the supports 14 can move in the triaxial directions, that is, not only up and down, but also left and right and back and forth. Six circular suction pads 13 are provided under the block 12 included in each of the suction jigs 11, and an end portion 13a of the suction pad 13 touches the surface of the flexible stacked body 3. As shown in FIG. 8, six suction pads 13 are arranged in series along an initial motion position near a separation starting point (in a short-side direction of the flexible stacked body 3). The suction pads 13 are each a member with a relatively small diameter. The suction pads 13 are fixed to the block 12 and connected with the vacuum pump P.

The end portion 13a of the suction pad 13 has a flat circular shape to make the suction easier, and is made of a synthetic resin elastic body such as synthetic rubber, silicon rubber, or polyurethane. Thus, when the suction pads 13 are brought into contact with the surface of the flexible stacked body 3, the suction pads 13 follow the flexibility of the flexible stacked body 3 and keep attached thereto because of their elasticity. With such a form of the suction pads, the number of suction points on the flexible stacked body 3 increases, and each of the suction jigs 11 sucks the flexible stacked body 3 with the plurality of suction pads 13. Accordingly, even when the flexible stacked body 3 changes in shape, the shape can be easily followed and the separation can be performed easily.

As a result, uniform suction without detachment of the suction pads 13 can be achieved. Even if some of the suction pads 13 are detached from the flexible stacked body 3, an accident such as a drop is not likely to occur. In this example, three suction jigs 11 are arranged along the initial motion position near the separation starting point (in the short-side direction of the flexible stacked body 3), which means 18 suction pads 13 in total are arranged there. Furthermore, movement of each of the suction jigs 11 can be individually controlled. However, the number of the suction jigs 11 and suction pads 13 is not limited, and can be increased, although not shown in the drawings. Moreover, individual operation of each of the suction pads 13 by an individual control becomes possible through modifying the structure of the block 12.

Furthermore, in this example, the suction jigs 11 are provided near the two sides of the flexible stacked body 3, one is the initial motion position near the separation starting point and the other is near the separation complete position. However, for smoother separation, the plurality of suction jigs 11 and suction pads 13 can also be arranged in a continuous manner over the whole area between the initial motion position near the separation starting point and the separation complete position. In that case, it is necessary that the suction pads and the like be controlled individually. The operation of the suction pads 13 is controlled by a control device 20.

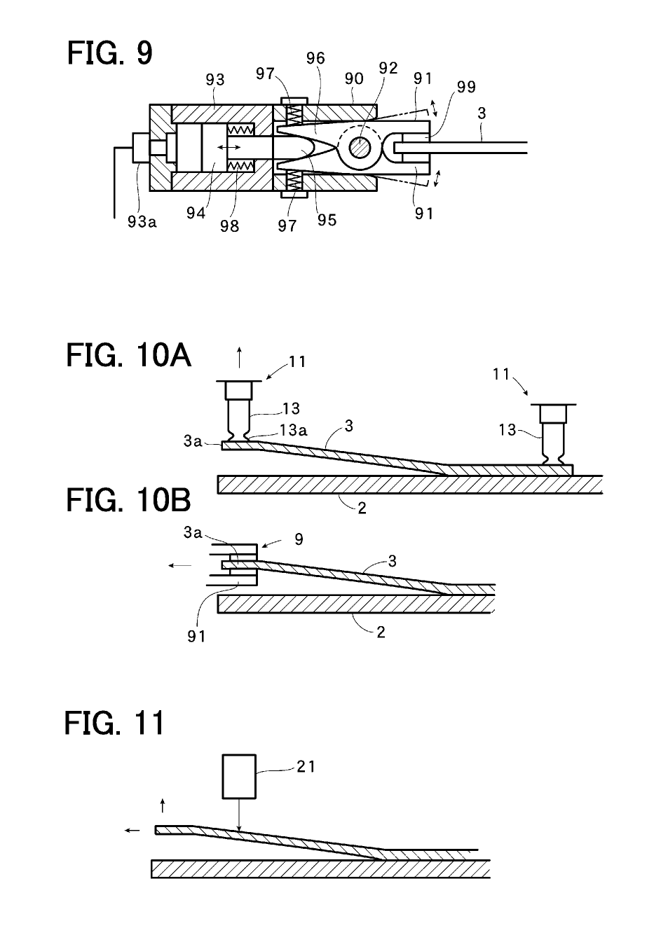

As shown in the drawings, two clamp jigs 9 are provided near the separation object 16. Similarly, the needle 17 and the nozzle 19 for supplying water are provided near the separation starting position of the flexible stacked body 3. The clamp jigs 9 are to hold the separated flexible stacked body 3, and can be configured to hold an object by the parallel movement of holding portions or can be configured to hold an object by oscillation via a fulcrum. In this example, the structure shown in FIG. 9 is used for example.

The clamp jig 9 shown in FIG. 9 is to hold the edge 3a of the flexible stacked body 3 by oscillating two arms 91 supported by a support 90 with a spindle 92. Owing to the piston movement of a cylinder 93 provided in the support 90, a cam 95 at an end portion of the piston 94, pinched by rear portions 96 of the arms 91, moves, and the cam movement opens or closes the arms 91. A spring 97 is provided on the outer side of each of the rear portions 96 of the arms 91 such that the spring 97 is between the rear portion 96 and the support 90. When the piston 94 does not move, the rear portion 96 of the arm 91 is pushed by the spring 97, such that a state where the arms 91 are open is maintained.

Furthermore, a spring 98 is provided in the cylinder 93 to press the piston 94 such that the piston 94 is positioned on the side opposite to the arms 91. For moving the piston 94, air is supplied to a port 93a of the cylinder 93 to move the piston 94 against the pressing force of the spring 98. Through this movement, the cam 95 pushes the rear portions 96 apart to close the arms 91. A pad 99 having softness is provided on a tip of the arm 91, and the edge 3a of the flexible stacked body 3 is held by the arms 91 with the pads 99 positioned therebetween. In this manner, the edge 3a is not damaged by being held. Although in this example the cam 95 is used as an operation member, a link motion mechanism may be used such that the movement of the piston is directly interlocked with the arms 91 to forcibly open or close the arms.

The holding force may be determined by the structure of the cylinder having predetermined capability. Furthermore, appropriate holding force may be obtained by changing the pressure of the air. Pinching and holding the edge 3a of the flexible stacked body 3, the claim jigs 9 maintain constant extensibility (tension) on the flexible stacked body 3 with which the flexible stacked body 3 to be separated remains unbent. In addition, even when the suction with the suction pads 13 fails, the flexible stacked body 3 can be continuously held by the claim jigs 9. In this manner, the clamp jigs 9 effectively function in uniform separation.

Although the detail is not shown, the needle 17 is a metal needle with a pointed tip, for example. The needle 17 is used to promote the separation in a certain region, by being stuck into a point near the separation starting position of the flexible stacked body 3 of the separation object 16, as shown in FIG. 7. The position where the needle 17 is inserted is set after an image is checked. Alternatively, the needle 17 is inserted into a predetermined angular position of the separation object 16. At approximately the same time as the needle insertion, water is supplied via the nozzle 19 to the cut 18. The supply of water can facilitate the separation and prevent electrostatic discharge damage.

When the separation object 16 is placed and fixed to the fixing stage 10 as described above, the suction jigs 11 are set at predetermined positions above the flexible stacked body 3 as shown in FIG. 4, and the suction pads 13 are brought into contact with the surface of the flexible stacked body 3 through a driving operation of the support 14. In this example, the separation starts from a corner of the separation object 16 (see FIG. 3). As schematically illustrated in FIG. 7, the sticking of the needle 17 reaches the separation layer 7 provided between the rigid substrate 2 and the flexible stacked body 3. After water is supplied, a corner of the flexible stacked body 3 is separated from the rigid substrate 2 and lifted by the suction jigs 11. The flexible stacked body 3 to be separated is made up of the element 4, the adhesive 5, and the flexible substrate 6, in this example (see FIG. 7).

Next, starting with the suction jig 11 on the side where the needle 17 has been stuck, suction with the suction jigs 11 arranged along the short side are sequentially carried out from this starting position (i.e., the suction jigs 11 start to be driven at intervals), as indicated by an arrow in FIG. 4, and the suction jigs 11 are lifted by the operation of the supports 14. In this manner, the three suction jigs 11 in this part are sequentially lifted and eventually held at the same predetermined level as shown in FIG. 5. That is, all the three suction jigs 11 in the short side direction of the flexible stacked body 3 are driven to be positioned at the predetermined positions above the fixing stage 10. At this time, the initial motion position, which is the edge 3a of the flexible stacked body 3 at the short side that corresponds to one side of the separation object 16 that is rectangular in this example, is uniformly separated.

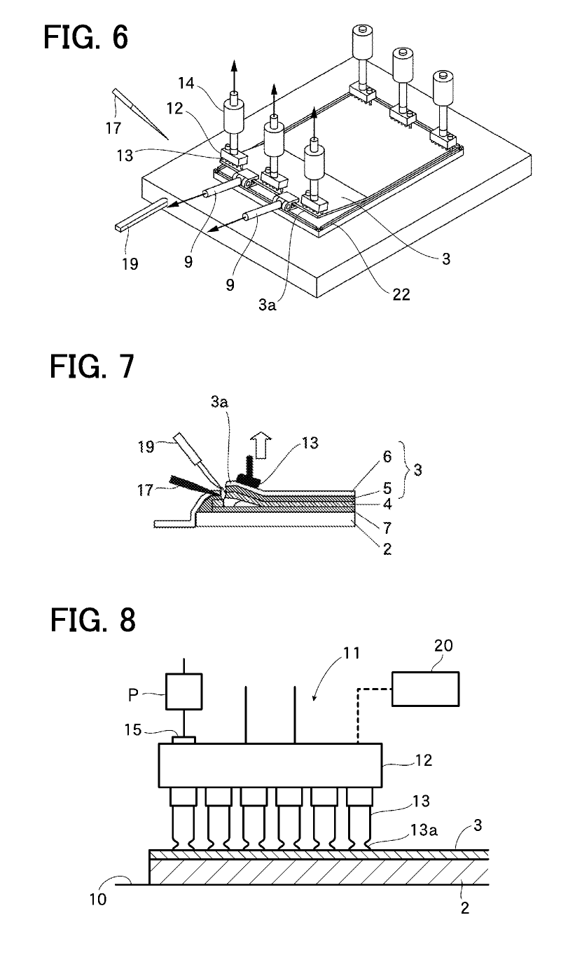

Next, the two clamp jigs 9 are inserted between the adjacent suction jigs 11 in a suction state, or set at the edge 3a side, as shown in FIG. 6. When the clamp jigs 9 are inserted into predetermined positions, the arms 91 of the claim jigs 9 are closed by the operation of the cylinders 93 in the clamp jigs 9, whereby the edge 3a of the flexible stacked body 3 is held as shown in FIG. 6. Subsequently, while the edge 3a of the flexible stacked body 3 is held, the suction jigs 11 and the clamp jigs 9 slightly and slowly move in a direction of separating only the flexible stacked body 3, as indicated by arrows in FIG. 6. Note that when the separation stops proceeding in the middle of the operation, a display defect may occur later from the position where the separation stopped. Therefore, it is desirable that the edge 3a of the flexible stacked body 3 is held by the clamp jigs 9 without stopping the separation (in other words, while the separation is performed using the suction jigs 11). Furthermore, there is also a case where a force of promoting the separation increases at the moment the clamp jigs 9 hold the edge 3a of the flexible stacked body 3 because of the intention to avoid stopping the separation, and a display defect occurs from that point. Therefore, the holding force or operation speed of the clam jigs 9 and/or the force of lifting the suction jigs 11 needs to be adjusted to appropriate value.

That is, the suction jigs 11 and the clamp jigs 9 move up and in a horizontal direction, in relation to each other. The clamp jigs 9 move up while providing a tension to the flexible stacked body 3 to maintain the tense state of the flexible stacked body 6. Although FIG. 6 indicates that the two clamp jigs 9 move parallel with each other, the two clamp jigs 9 can move in oblique directions (indirections not parallel to each other) also. The two clamp jigs 9 are controlled such that the flexible stacked body 3 in the middle of separation is kept in a uniformly-tense state without a wrinkle or the like.

A structure of the separation using the suction jigs 11 and the clamp jigs 9 is illustrated in FIGS. 10A and 10B. The flexible stacked body 3 to be separated is lifted by the suction jigs 11 and stretched by the clamp jigs 9 to be constantly in a tense state, thereby being stably separated without being folded, bent, nor warped. For easier understanding, FIGS. 10A and 10B show the separation jigs 11 and the clamp jig 9, respectively, in the same separation position.

The suction jigs 11 are also provided at the separation complete position of the flexible stacked body 3. Those suction jigs 11 press the flexible stacked body 3 in the middle of separation, and when the separation completes, lift the flexible stacked body 3 with the other suction jigs 11 at the initial motion position to complete the separation. This separation process is performed in accordance with the progress of the separation, while controlling the moving speed, moving directions, moving force, and the like of the suction jigs 11 and the clamp jigs 9, in order not to cause breakage or the like in the separation.

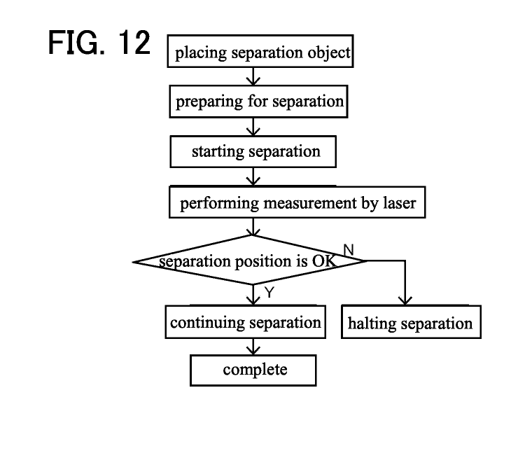

Next, an example of methods to secure the separation state will be explained. In the example shown in FIG. 11, a displacement meter such as a laser measuring instrument or a measuring instrument such as a position sensor is utilized. In this example, the separation operation can be performed while the position of an edge of the flexible stacked body 3 is accurately monitored. The summary of this process is shown as a flow chart in FIG. 12. As described above, after the separation object 16 is placed on the fixing stage 10, the suction jigs 11, the clamp jigs 9, and the like are appropriately positioned, and the separation starts. In the separation process, a laser measuring instrument 21 or the like is provided above a predetermined position of the flexible stacked body 3.

The position of the flexible stacked body 3 in the process of being separated is measured by the laser measuring instrument 21. In the case where the position of the flexible stacked body 3 is found by the measurement to be out of the predetermined position more than an allowable limit, the separation is halted and the separation process stops. As long as the measurement results have no problem, the separation process continues and completes. In this manner, accurate monitoring of the separation position in the separation process can prevent problems such as breakage of the flexible stacked body 3.

### Other Embodiments

Although embodiments of the present invention are explained above, it is needless to say that the invention is not limited thereto. For example, although the suction jig is shown as a rectangular block in the drawings, the suction jig may have a different shape. Although the suction pad is explained as having a circular suction portion, it may have a different shape. Furthermore, different suction pads may have different sizes. The other clamp methods than the clamp jig in the above example may be employed. In addition, although a needle is provided at the separation starting position in the above example, a member having a different shape may be employed as long as the member has a function similar to the needle.

Although the nozzle is used for supplying a liquid such as water in the above description, a gas may be supplied. Although the substrate, the flexible stacked body, and the component are each explained as rectangular in shape, one embodiment of the present invention is a concept including the other shapes such as an ellipse, a circle, and the like because there are flexible devices, equipment, and modules having such shapes. Furthermore, even when the substrate or the component of the above-described embodiment is rectangular, if a cut of an elliptical shape, a circular shape, or another shape is given in a flexible stacked body to be separated, a device, equipment, or a module with a desired shape can be fabricated. Therefore, the shapes of the substrate, the flexible stacked body, and the component in the present invention are not limited to rectangles.

### REFERENCE NUMERALS

1: separation apparatus, 2: rigid substrate, 3: flexible stacked body, 4: element, 5: adhesive, 6: flexible substrate, 7: separation layer, 8: suction mechanism, 9: clamp jig, 10: fixing stage, 11: suction jig, 12: block, 13: suction pad, 14: support, 15: inlet, 16: separation object, 17: needle, 18: cut, 19: nozzle, 20: control device, 21: laser measuring instrument

This application is based on Japanese Patent Application serial no. 2014-095580 filed with Japan Patent Office on May 3, 2014, the entire contents of which are hereby incorporated by reference.

1. A separation apparatus configured to separate a flexible stacked body from a substrate, comprising:
a fixing jig capable of fixing the substrate;
suction jigs over the fixing jig, the suction jigs each comprising suction pads capable of being attached to the flexible stacked body by suction; and
a clamp jig capable of holding an edge of the flexible stacked body separated from the substrate by the suction jigs.

2. The separation apparatus according to claim 1, wherein a shape of the substrate is a square or a rectangle.

3. The separation apparatus according to claim 1, further comprising:
a needle capable of sticking a separation starting point for separating the flexible stacked body from the substrate.

4. The separation apparatus according to claim 1, further comprising:
a nozzle capable of supplying a liquid to a separation area of the flexible stacked body.

5. The separation apparatus according to claim 1, further configured so that the suction jigs comprise:
first suction jigs placed in a first position of the flexible stacked body where a separation starts; and
second suction jigs placed in a second position of the flexible stacked body where the separation completes.

6. The separation apparatus according to claim 5, further configured so that the suction jigs comprise a third suction jigs placed in a position between the first position and the second position.

7. The separation apparatus according to claim 1, wherein an end portion of the suction pad has a circular shape.

8. The separation apparatus according to claim 1, wherein the suction pads have different sizes.

9. A separation apparatus configured to separate a flexible stacked body from a substrate, comprising:
a fixing jig capable of fixing the substrate;
suction jigs over the fixing jig, the suction jigs each comprising suction pads capable of being attached to the flexible stacked body by suction;
a clamp jig capable of holding an edge of the flexible stacked body separated from the substrate by the suction jigs; and
a measuring instrument capable of sensing a separating position of the flexible stacked body separated from the substrate.

10. The separation apparatus according to claim 9, wherein a separation operation is controlled in accordance with a measurement by the measuring instrument.

11. The separation apparatus according to claim 9, wherein a shape of the substrate is a square or a rectangle.

12. The separation apparatus according to claim 9, further comprising:
a needle capable of sticking a separation starting point for separating the flexible stacked body from the substrate.

13. The separation apparatus according to claim 9, further comprising:
a nozzle capable of supplying a liquid to a separation area of the flexible stacked body.

14. The separation apparatus according to claim 9, further configured so that the suction jigs comprise:
first suction jigs placed in a first position of the flexible stacked body where a separation starts; and
second suction jigs placed in a second position of the flexible stacked body where the separation completes.

15. The separation apparatus according to claim 14, further configured so that the suction jigs comprise a third suction jigs placed in a position between the first position and the second position.

16. The separation apparatus according to claim 9, wherein an end portion of the suction pad has a circular shape.

17. The separation apparatus according to claim 9, wherein the suction pads have different sizes.

18. A method for separating a flexible stacked body from a substrate, comprising steps of:
fixing the substrate by a fixing jig;
attaching suction pads of each of suction jigs to the flexible stacked body by suction; and
holding, by a clamp jig, an edge of the flexible stacked body separated from the substrate.

19. The method according to claim 18, further comprising:
sensing, by a measuring instrument, a separating position of the flexible stacked body separated from the substrate.

20. The method according to claim 19, wherein a separation operation is controlled in accordance with a measurement by the measuring instrument.

21. The method according to claim 18, wherein a shape of the substrate is a square or a rectangle.

22. The method according to claim 18, further comprising:
sticking, by a needle, a separation starting point for separating the flexible stacked body from the substrate.

23. The method according to claim 18, further comprising:
supplying a liquid to a separation area of the flexible stacked body by a nozzle.

24. The method according to claim 18, further comprising:
placing first suction jigs of the suction jigs in a first position of the flexible stacked body where a separation starts; and
placing second suction jigs of the suction jigs in a second position of the flexible stacked body where the separation completes.

25. The method according to claim 24, further comprising:
placing a third suction jigs in a position between the first position and the second position.

26. The method according to claim 18, wherein an end portion of the suction pad has a circular shape.

27. The method according to claim 18, wherein the suction pads have different sizes.
